(19) United States
(12) Patent Application Publication
(10) Pub. No.: US 2026/0211289 A1
(43) Pub. Date: Jul. 23, 2026

(54) DISPLAY APPARATUS AND METHORD OF MANUFACTURING SAME

(71) Applicant: LG Display Co., Ltd., Seoul (KR)

(72) Inventors: Cheol Woo PARK, Paju-si (KR); Seong Jun CHO, Paju-si (KR); Chan Soo PARK, Paju-si (KR); Gyu Sik WON, Paju-si (KR); Hyung Beom SHIN, Paju-si (KR); Chan Ho LEE, Paju-si (KR)

(73) Assignee: LG Display Co., Ltd., Seoul (KR)

(21) Appl. No.: 19/423,754

(22) Filed: Dec. 17, 2025

(30) Foreign Application Priority Data
Jan. 23, 2025 (KR) 10-2025-0010427

(51) Int. Cl. G02F 1/1362; G02F 1/1368

(52) U.S. Cl. CPC G02F 1/136236; G02F 1/136227; G02F 1/136277; G02F 1/136295; G02F 1/1368

(57) ABSTRACT

A display apparatus and a method of manufacturing the same, which are capable of reducing the number of mask processes, are discussed. The display apparatus can include gate lines extending in a first direction, data lines extending in a second direction intersecting the gate lines and extending discontinuously in an area overlapping the gate lines, a thin film transistor having an active layer and disposed in a pixel area defined by the gate lines and the data lines intersecting each other, and a pixel electrode connected to the thin film transistor. The data lines extending discontinuously in the area overlapping the gate lines are electrically connected to each other by the active layer of the thin film transistor.

### CROSS-REFERENCE TO RELATED APPLICATIONS

This application claims priority to Korean Patent Application No. 10-2025-0010427, filed in the Republic of Korea on Jan. 23, 2025, which is hereby expressly incorporated by reference as if fully set forth herein.

### BACKGROUND OF THE DISCLOSURE

### Field of the Disclosure

The present disclosure relates to a display apparatus, and more particularly, to a display apparatus and a method of manufacturing the same, which are capable of reducing the number of mask processes.

### Discussion of the Related Art

A video display apparatus that displays various information on a screen is core technology of the information and communication age and is evolving toward being thinner, lighter, more portable, and higher performance. Accordingly, a display apparatus that can be manufactured in a lightweight and thin form is receiving attention.

Specific examples of such a display apparatus include a liquid crystal display (LCD) apparatus, a quantum dot (QD) display apparatus, a field emission display (FED) apparatus, and an organic light emitting diode (OLED) display apparatus.

A liquid crystal display apparatus is a flat panel display apparatus that is widely used. The liquid crystal display apparatus has a field generating electrode such as a pixel electrode, a common electrode, etc., and serves to display an image by applying a voltage to the field generating electrode to generate an electric field in a liquid crystal layer and thereby determine the orientation of liquid crystal molecules in the liquid crystal layer and control polarization of incident light.

A a liquid crystal display apparatus employing FFS (fringe field switching) or IPS (in-plane switching), which forms multiple domains with different liquid crystal orientations in one pixel, is widely used to implement a wide viewing angle.

Each pixel of such a liquid crystal display apparatus can have a thin film transistor and a pixel electrode. An example of the thin film transistor can include a coplanar-type thin film transistor in which a semiconductor is placed at the bottom and a gate insulating film, a gate electrode, and source/drain electrodes are sequentially disposed thereon.

A liquid crystal display apparatus provided with such a coplanar-type thin film transistor is manufactured using eight mask processes. Hence, the production cost can increase due to many mask processes.

### SUMMARY OF THE DISCLOSURE

An object of the present disclosure is to provide a display apparatus and a method of manufacturing the same, which are capable of reducing the number of mask processes.

The object of the present disclosure is not limited to the foregoing, and other objects not mentioned herein will be clearly understood by those skilled in the art from the following description.

An embodiment of the present disclosure provides a display apparatus, including gate lines extending in a first direction, data lines extending in a second direction intersecting the gate lines and extending discontinuously in an area overlapping the gate lines, a thin film transistor having an active layer and disposed in a pixel area defined by the gate lines and the data lines intersecting each other, and a pixel electrode connected to the thin film transistor, in which the data lines extending discontinuously in the area overlapping the gate lines are electrically connected to each other by the active layer of the thin film transistor.

Another embodiment of the present disclosure provides a method of manufacturing a display apparatus comprising, forming an active layer on a substrate, the active layer having a source area, a channel area and a drain area and having a semiconductor layer and a conductive layer remains by stacking a semiconductor layer and the conductive layer laminated thereon, wherein the conductive layer corresponding to the channel area is removed, forming a gate insulating film on the substrate on which the active layer is disposed, forming a first contact hole to expose the drain area of the active layer and second and third contact holes to expose the source area of the active layer by selectively removing the gate insulating film, forming gate lines extending in a first direction on the gate insulating film, a gate electrode protruding from the gate lines, and data lines extending in a second direction intersecting the gate lines to extend discontinuously in an area overlapping the gate lines, forming a first protective film on the front surface of the substrate to cover the gate lines, the data lines, and the gate electrode, forming a planarization layer on the first protective film, forming a fourth contact hole by selectively removing the first protective film and the planarization layer at a location where the first contact hole is formed, forming a common electrode and a common line on the planarization layer, forming a second protective film on the front surface of the substrate where the common electrode and the common line are disposed, forming a fifth contact hole by selectively removing the second protective film corresponding to a location where the fourth contact hole is formed, and forming a pixel electrode on the second protective film so as to be electrically connected to the drain area through the first, fourth and fifth contact holes.

Specific details of other embodiments of the present disclosure are included in the detailed description and drawings.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a block diagram showing a display apparatus according to an embodiment of the present disclosure;

FIG. 2 is a circuit diagram of a pixel included in the display apparatus according to an embodiment of the present disclosure;

FIG. 3 is a plan view showing a pixel of a liquid crystal display panel according to an embodiment of the present disclosure;

FIG. 4 is a cross-sectional view of a thin film transistor array substrate taken along line I-I′ of FIG. 3; and

FIGS. 5A to 5L are cross-sectional views showing a process of manufacturing the thin film transistor array substrate of the liquid crystal display panel according to an embodiment of the present disclosure, taken along line I-I′ of FIG. 3.

### DETAILED DESCRIPTION OF THE EMBODIMENTS

Hereinafter, various embodiments of the present disclosure will be described in conjunction with the accompanying drawings. The same reference numerals throughout the specification indicate substantially the same components.

In the following description, if it is determined that a detailed description of technology or configurations related to the present disclosure can unnecessarily obscure the gist of the present disclosure, the detailed description will be omitted. Further, the component names used in the following description are selected in consideration of the ease of writing the specification, and can be different from the part names of the actual product.

The shapes, sizes, ratios, angles, numbers, etc. disclosed in the drawings for explaining various embodiments of the present disclosure are examples, and therefore, the present disclosure is not limited to the matters depicted in the drawings. Like reference numerals designate like components throughout the present disclosure.

In addition, when describing the present disclosure, if it is determined that a detailed description of related known technology can unnecessarily obscure the gist of the present disclosure, the detailed description is omitted.

When the terms “include,” “have,” “made of,” etc. mentioned herein are used, other parts can be added unless “only” is used. In the case where a component is expressed in the singular, it includes the case of including the plural unless explicitly stated otherwise.

In interpreting the components included in various embodiments of the present disclosure, even if there is no separate explicit description, it is interpreted as including an error range.

In describing various embodiments of the present disclosure, in the case of describing a positional relationship, for example, “on,” “above,” “below,” “next to,” etc., when the positional relationship of two parts is described, one or more other parts can be located between the two parts unless “immediately” or “directly” is used.

In describing various embodiments of the present disclosure, in the case of describing a temporal relationship, for example, “after,” “subsequent to,” “then,” “before,” etc., when the temporal causality is explained, it can also include non-continuous cases unless “immediately” or “directly” is used.

In describing various embodiments of present disclosure, terms such as “first,” “second,” etc. can be used to describe various components, but these terms are only used to distinguish between identical or similar components. Accordingly, unless stated otherwise, a component described as “first” in the present disclosure can be identical to a component described as “second” within the technical spirit of the present disclosure. Further, the term “can” fully encompasses all the meanings and coverages of the term “may” and vice versa.

The features in various embodiments of the present disclosure can be partially or entirely coupled or combined with each other, technically various interlocking and driving are possible, and various embodiments can be implemented independently of each other or together in an association relationship.

Hereinafter, a display apparatus according to various embodiments of the present disclosure will be described referring to the drawings. All the components of each display apparatus/device according to all embodiments of the present disclosure are operatively coupled and configured.

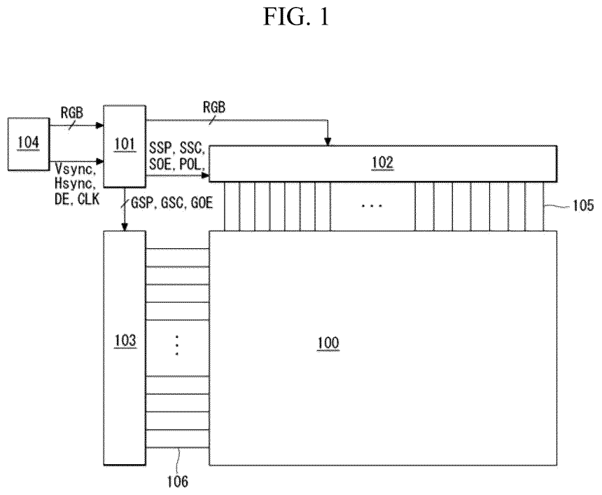

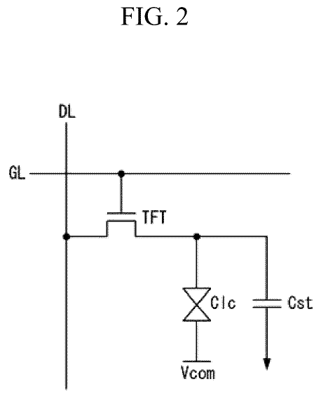

FIG. 1 is a block diagram showing a display apparatus according to an embodiment of the present disclosure. FIG. 2 is a circuit diagram of a pixel included in the display apparatus according to an embodiment of the present disclosure. The pixel configuration of FIG. 2 can be used in each of the pixels included in the display apparatus of FIG. 1.

Referring to FIGS. 1 and 2, the display apparatus according to an embodiment of the present disclosure can include a liquid crystal display panel 100, a data driving circuit 102, a gate driving circuit 103, and a timing controller 101, as shown in FIG. 1. A backlight unit can be disposed below the liquid crystal display panel 100 to uniformly radiate light to the liquid crystal display panel 100. The backlight unit can be provided as a direct-type backlight unit or an edge-type backlight unit.

The liquid crystal display panel 100 can include a thin film transistor array substrate (or a first substrate) and a color filter array substrate (or a second substrate) facing each other with a liquid crystal layer therebetween. A pixel array configured to display a video signal can be formed on the liquid crystal display panel 100. The pixel array can include a plurality of pixels arranged in a matrix form by data lines and gate lines intersecting each other. The plurality of pixels can have red pixels, green pixels, and blue pixels, but other variations are possible. Neighboring pixels can share the same data lines. The pixels can serve to display an image of a video signal by adjusting the quantity of light transmitted depending on the electric field difference between the data voltage applied to the pixel electrode and the common voltage applied to the common electrode. The common electrode can be formed on the thin film transistor array substrate along with the pixel electrode in a horizontal field driving mode such as a FFS (fringe field switching) mode or IPS (in-plane switching) mode.

The thin film transistor array substrate can include the data lines, the gate lines, thin film transistors, pixel electrodes connected 1:1 to the thin film transistors, storage capacitors Cst connected 1:1 to the pixel electrodes, etc. A black matrix and color filters can be formed on the color filter array substrate of the liquid crystal display panel 100. In an embodiment of the present disclosure, a common electrode is formed on the thin film transistor array substrate. A polarizing plate can be attached to each of the color filter array substrate and the thin film transistor array substrate of the liquid crystal display panel 100.

The data driving circuit 102 can include a plurality of source driver integrated circuits (ICs). The output channels of the source driver ICs can be connected 1:1 to the data lines of the pixel array. Each of the source driver ICs can receive digital video data from the timing controller 101. The source driver ICs can serve to convert the digital video data into positive/negative data voltages in response to a source timing control signal from the timing controller 101 and supply the data voltages to the data lines of the pixel array through the output channels. The source driver ICs can serve to supply data voltages of opposite polarities to adjacent data lines under the control of the timing controller 101, maintain the polarity of the data voltage supplied to each data line the same for one frame period, and then invert the polarity of the data voltage in the next frame period. Therefore, the source driver ICs are able to maintain the polarity of the data voltages the same for one frame period and invert the polarity of the data voltages in one frame period cycle, substantially the same as the column inversion method.

The gate driving circuit 103 can serve to sequentially supply scan pulses (gate pulses) to the gate lines of the pixel array in response to a gate timing control signal from the timing controller 101. The timing controller 101 can serve to supply digital video data input from an external system board 104 to the source driver ICs of the data driving circuit 102. The timing controller 101 is able to generate a source timing control signal for controlling the operation timing of the data driving circuit 102 and a gate timing control signal for controlling the operation timing of the gate driving circuit 103.

Referring to FIG. 2, in the display apparatus according to an embodiment of the present disclosure, the digital video data can be converted into an analog data voltage based on a gamma reference voltage, which can then be supplied to a data line DL, and simultaneously, a scan pulse can be supplied to a gate line GL, charging the data voltage to a liquid crystal cell Clc. To this end, the gate electrode of the thin film transistor is connected to the gate line GL, the source electrode is connected to the data line DL, and the drain electrode of the thin film transistor is connected to the pixel electrode of the liquid crystal cell Clc and one electrode of the storage capacitor Cst1. A common voltage Vcom is supplied to the common electrode of the liquid crystal cell Clc. The storage capacitor Cst1 serves to maintain the voltage of the liquid crystal cell Clc constant by charging the data voltage applied from the data line DL when the thin film transistor is turned on. When the scan pulse is applied to the gate line GL, the thin film transistor is turned on, forming a channel between the source electrode and the drain electrode and thus supplying the data voltage of the data line DL to the pixel electrode of the liquid crystal cell Clc. As such, alignment of the liquid crystal molecules of the liquid crystal cell Clc is changed due to the electric field between the pixel electrode and the common electrode, thereby varying the incident light.

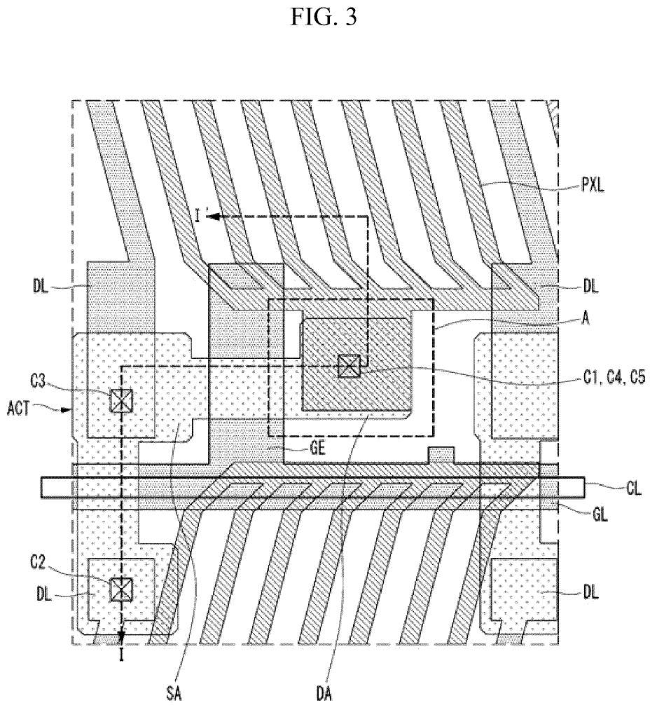

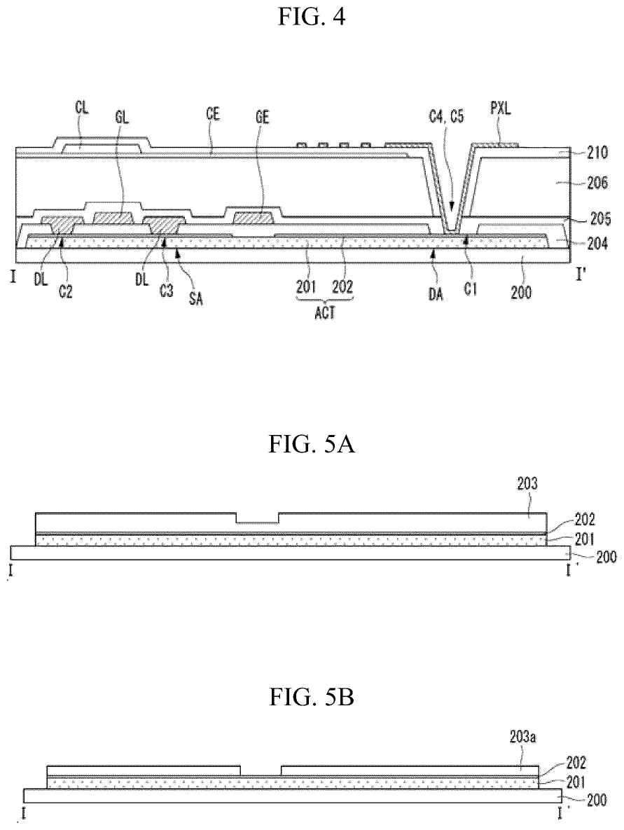

FIG. 3 is a plan view showing a pixel of the liquid crystal display panel according to an embodiment of the present disclosure. FIG. 4 is a cross-sectional view of the thin film transistor array substrate taken along line I-I′ of FIG. 3.

Referring to FIGS. 3 and 4, the liquid crystal display panel 100 according to an embodiment of the present disclosure can have a pixel defined by gate lines GL extending in a first direction and data lines DL extending in a second direction intersecting the gate lines GL. The data lines DL can extend discontinuously in an area overlapping the gate lines GL. Further, a common line CL can be provided to overlap the gate lines GL in a direction parallel to the gate lines GL.

The pixel defined by the gate lines GL and the data lines DL intersecting each other can include a thin film transistor TR and a pixel electrode PXL connected to the thin film transistor TR. The pixel electrode PXL can have a plurality of slits to implement the FFS (fringe field switching) mode, which will be described later.

The thin film transistor TR can include an active layer ACT, a gate electrode GE protruding from the gate lines GL and overlapping the active layer ACT, a source area SA is electrically connected to the data lines DL and formed in the active layer ACT at one side of the gate electrode GEt, and a drain area DA electrically connected to the pixel electrode PXL and formed in the active layer ACT at the remaining side of the gate electrode GE.

The data lines DL that extend discontinuously in an area overlapping the gate lines GL can be electrically connected to each other by the active layer ACT.

The cross-sectional structure of one pixel of the thin film transistor array substrate of the liquid crystal display panel is described as follows.

The active layer ACT can be disposed on a substrate 200. The active layer ACT can include a semiconductor layer 201 and a conductive layer 202. For example, the active layer ACT can include a semiconductor layer 201 disposed on the substrate 200 and a conductive layer 202 disposed on the semiconductor layer 201. The conductive layer 202 may not be formed under the gate electrode GE. Accordingly, respective areas of the active layer ACT on which the conductive layer 202 is disposed can be referred to as a source area SA and a drain area DA.

For example, the semiconductor layer 201 can include any one selected from among amorphous silicon, polycrystalline silicon, low-temperature polysilicon (LTPS), and an oxide semiconductor. The conductive layer 202 can include either a metal layer or a semiconductor layer doped with impurities. For example, the conductive layer 202 can be made of a polycrystalline semiconductor material doped with Group 5 or Group 3 impurity ions, such as phosphorus (P) or boron (B), at a predetermined concentration.

The data lines DL that extend discontinuously in an area overlapping the gate lines GL can be electrically connected to each other by the conductive layer 202 of the active layer ACT.

A gate insulating film 204 can be disposed on the substrate 200 on which the active layer ACT including the semiconductor layer 201 and the conductive layer 202 is placed. For example, the gate insulating film 204 can be used by stacking an inorganic layer such as a silicon oxide (SiO₂) film or a silicon nitride (SiNx) film in a monolayer or multilayer structure.

The gate insulating film 204 can have a first contact hole C1 so that the drain area DA is exposed. The gate insulating film 204 can have second and third contact holes C2, C3 so that the source area SA is exposed. The first contact hole C1 can be a contact hole configured to connect a pixel electrode PXL. The second and third contact holes C2, C3 can be contact holes configured to electrically connect the data lines DL that extend discontinuously in an area overlapping the gate lines GL.

The gate lines GL extending in the first direction and the data lines DL extending in the second direction intersecting the gate lines GL can be disposed on the gate insulating film 204. The data lines DL can extend discontinuously in an area overlapping the gate lines GL.

The ends of the data lines DL that extend discontinuously in the area overlapping the gate lines GL can be connected to the conductive layer 202 of the active layer ACT through the second and third contact holes C2, C3. Accordingly, the ends of the data lines DL that extend discontinuously in the area overlapping the gate lines GL can be electrically connected to each other through the conductive layer 202 of the active layer ACT.

The gate electrode GE protruding from the gate lines GL can be disposed on the gate insulating film 204 in a portion of the active layer ACT from which the conductive layer 202 is removed.

The gate lines GL, the data lines DL, and the gate electrode GE can be formed of the same metal material. For example, the gate lines GL, the data lines DL, and the gate electrode GE can have a monolayer or multilayer structure made of any one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

A first protective film 205 can be disposed to cover the gate lines GL, the data lines DL, and the gate electrode GE. For example, the first protective film 205 can be used by stacking an inorganic layer such as a silicon oxide (SiO₂) film or a silicon nitride (SiNx) film in a monolayer or multilayer structure.

A planarization layer 206 can be disposed on the first protective film 205 to achieve surface planarization. For example, the planarization layer 206 can be an organic insulating film made of photoacryl, polyimide, benzocyclobutene resin, or acrylate resin. The first protective film 205 and the planarization layer 206 can include a fourth contact hole C4 at the location where the first contact hole C1 is formed.

A common electrode CE and a common line CL can be disposed on the planarization layer 206. The common electrode CE can be integrally formed on the front surface of the substrate 200 excluding the first, fourth, and fifth contact holes C1, C4, C5. For example, the common electrode CE can be integrally formed on the front surface of the substrate 200 excluding the area “A” shown in FIG. 3. The common electrode CE can be made of a transparent conductive film. The transparent conductive film can be made of a transparent conductive material, such as ITO (indium tin oxide) or IZO (indium zinc oxide). The common line CL can be disposed on the common electrode CE. The common electrode CE can be electrically connected to the common line CL. A common voltage can be applied to the common electrode CE through the common line CL. The common line CL can be formed of a metal material. For example, the common line CL can have a monolayer or multilayer structure made of any one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

A second protective film 210 can be disposed on the front surface of the substrate where the common electrode CE and the common line CL are disposed. For example, the second protective film 210 can be used by stacking an inorganic layer such as a silicon oxide (SiO₂) film or a silicon nitride (SiNx) film in a monolayer or multilayer structure. The second protective film 210 can include a fifth contact hole C5 at the location where the fourth contact hole C4 is formed.

A pixel electrode PXL can be disposed on the second protective film 210. The pixel electrode PXL can be made of a transparent conductive film, like the common electrode CE. The pixel electrode PXL can be electrically connected to the drain area DA of the thin film transistor Tr through the first, fourth and fifth contact holes C1, C4 and C5. In order to form a fringe field depending on the voltage applied to the common electrode CE and the voltage applied to the pixel electrode PXL, the pixel electrode PXL can have a plurality of slits.

A color filter array substrate including a black matrix layer formed in a portion excluding each pixel area on a counter substrate, a color filter layer formed in each pixel area, an overcoat layer covering the black matrix layer and the color filter layer and the thin film transistor array substrate described above are bonded with a predetermined gap therebetween, and the gap between the thin film transistor array substrate and the color filter array substrate is filled with a liquid crystal layer, thereby manufacturing a liquid crystal display panel.

The method of manufacturing the liquid crystal display panel thus configured according to one or more embodiments of the present disclosure is described as follows.

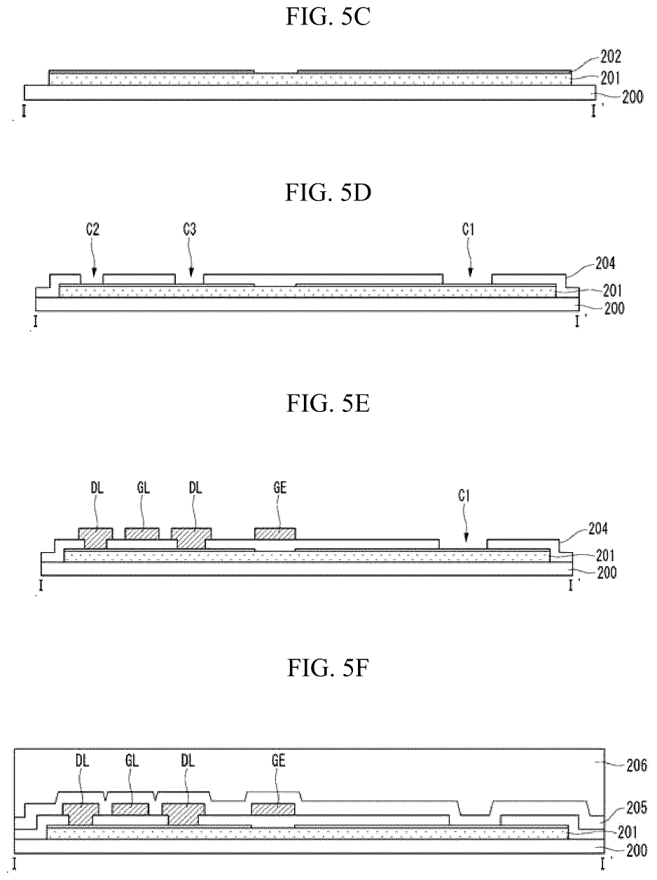

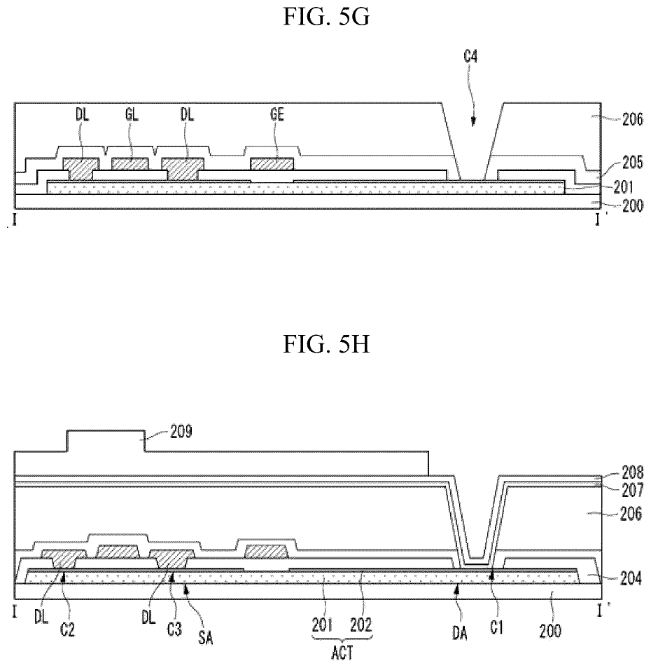

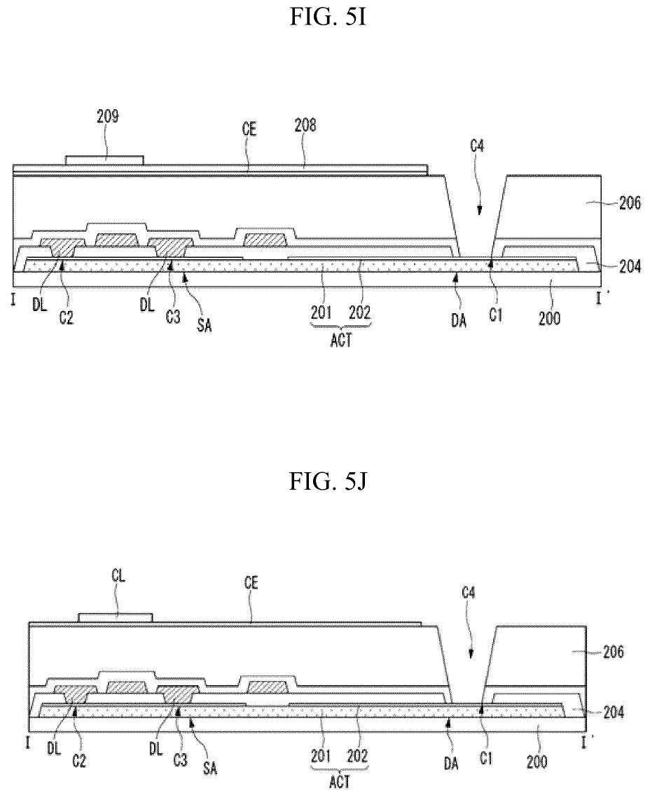

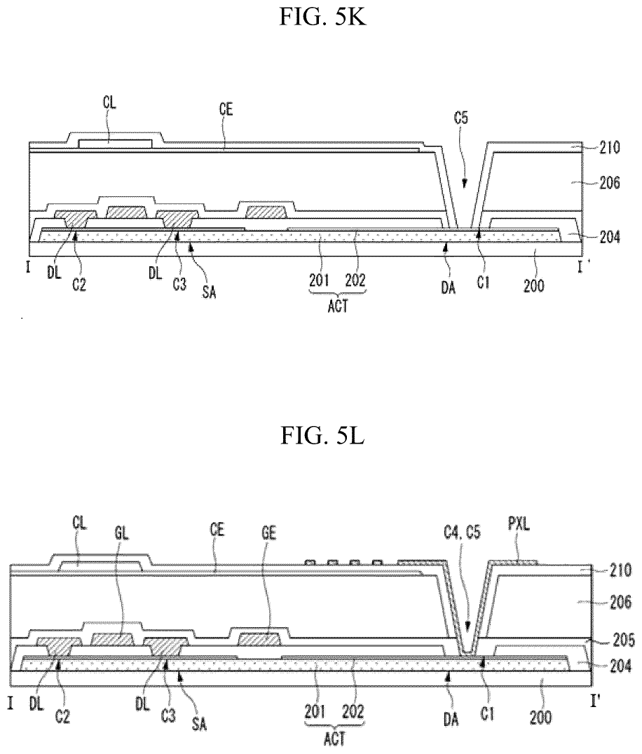

FIGS. 5A to 5L are cross-sectional views showing a process of manufacturing the thin film transistor array substrate of the liquid crystal display panel according to an embodiment of the present disclosure, taken along line I-I′ of FIG. 3.

Referring to FIG. 5A, a semiconductor layer 201 and a conductive layer 202 are sequentially formed on a substrate 200. For example, the semiconductor layer 201 can include any one selected from among amorphous silicon, polycrystalline silicon, low-temperature polysilicon (LTPS), and an oxide semiconductor. The conductive layer 202 can include either a metal layer or a semiconductor layer doped with impurities. For example, the conductive layer 202 can be made of a polycrystalline semiconductor material doped with Group 5 or Group 3 impurity ions, such as phosphorus (P) or boron (B), at a predetermined concentration.

Then, a photoresist is deposited on the conductive layer 202, and a photoresist pattern 203 is formed to define an active layer ACT through exposure and development processes using a halftone mask. The photoresist pattern 203 is located on the conductive layer 202 in an area corresponding to the active layer ACT. The photoresist pattern 203 is formed so that a region corresponding to the location where the gate electrode GE is to be formed or the channel area of the thin film transistor is thinner than the other regions.

To form the active layer ACT, the semiconductor layer 201 and the conductive layer 202 are etched through an etching process using the photoresist pattern 203 as a mask.

Referring to FIG. 5B, the photoresist pattern 203 is ashed. For example, among the photoresist pattern 203, the photoresist pattern 203 corresponding to the region having a relatively low thickness is removed and the photoresist pattern 203 corresponding to the region having a relatively high thickness is left behind.

Referring to FIG. 5C, the conductive layer 202 exposed by the ashed photoresist pattern 203a is etched using the ashed photoresist pattern 203a as a mask. Accordingly, the active layer ACT has a stack structure of the semiconductor layer 201 and the conductive layer 202, and the conductive layer 202 may not be formed at a location corresponding to the channel area of the thin film transistor. The conductive layer 202 remaining at both sides after removal of the conductive layer 202 can become a source area SA and a drain area DA. As such, the first mask is used.

Referring to FIG. 5D, a gate insulating film 204 is formed on the substrate 200 on which the active layer ACT including the semiconductor layer 201 and the conductive layer 202 is disposed. For example, the gate insulating film 204 can be used by stacking an inorganic layer such as a silicon oxide (SiO₂) film or a silicon nitride (SiNx) film in a monolayer or multilayer structure.

By selectively removing the gate insulating film 204 through exposure and etching processes using a mask, a first contact hole C1 is formed so that the drain area DA of the active layer ACT is exposed, and second and third contact holes C2, C3 are formed so that the source area SA of the active layer ACT is exposed. The first contact hole C1 can be a contact hole configured to connect a pixel electrode PXL. The second and third contact holes C2, C3 can be contact holes configured to electrically connect the data lines DL that extend discontinuously in an area overlapping the gate lines GL. As such, the second mask is used.

Referring to FIG. 5E, a metal layer is deposited on the gate insulating film 204, and the metal layer is selectively removed through exposure and etching processes using a mask, thereby forming gate lines GL extending in the first direction, a gate electrode GE protruding from the gate lines GL, and data lines DL extending in the second direction intersecting the gate lines GL. The data lines DL are formed to extend discontinuously in an area overlapping the gate lines GL.

The data lines DL that extend discontinuously in the area overlapping the gate lines GL can be electrically connected to each other by the conductive layer 202 of the active layer ACT. For example, the ends of the data lines DL that extend discontinuously in the area overlapping the gate lines GL are electrically connected to the conductive layer 202 of the active layer ACT through the second and third contact holes C2, C3. Accordingly, the ends of the data lines DL that extend discontinuously in the area overlapping the gate lines GL can be electrically connected to each other through the conductive layer 202 of the active layer ACT.

Further, the gate electrode GE protruding from the gate lines GL is formed on the gate insulating film 204 in a portion of the active layer ACT from which the conductive layer 202 is removed.

The gate lines GL, the data lines DL, and the gate electrode GE can be formed of the same metal material. For example, the gate lines GL, the data lines DL, and the gate electrode GE can have a monolayer or multilayer structure made of any one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto. As such, the third mask is used.

Referring to FIG. 5F, a first protective film 205 is formed on the front surface of the substrate to cover the gate lines GL, the data lines DL, and the gate electrode GE. For example, the first protective film 205 can be used by stacking an inorganic layer such as a silicon oxide (SiO₂) film or a silicon nitride (SiNx) film in a monolayer or multilayer structure.

A planarization layer 206 is formed on the first protective film 205 to achieve surface planarization. For example, the planarization layer 206 can be an organic insulating film made of photoacryl, polyimide, benzocyclobutene resin, or acrylate resin.

Referring to FIG. 5G, a fourth contact hole C4 is formed by selectively removing the first protective film 205 and the planarization layer 206 at the location where the first contact hole C1 is formed, through exposure and etching processes using a mask. As such, the fourth mask is used.

Referring to FIG. 5H, a transparent conductive film 207 and a metal layer 208 are sequentially formed on the planarization layer 206. For example, the transparent conductive film 207 can be made of a transparent conductive material such as ITO (indium tin oxide) or IZO (indium zinc oxide). The metal layer 208 can have a monolayer or multilayer structure made of any one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

A photoresist is deposited on the metal layer 208, and a photoresist pattern 209 is formed to define a common electrode and a common line through exposure and development processes using a halftone mask. The photoresist pattern 209 is formed so that a region corresponding to the location where the common line CL is to be formed is thicker than the other regions.

Referring to FIG. 5I, the transparent conductive film 207 and the metal layer 208 are etched through an etching process using the photoresist pattern 209 as a mask. The photoresist pattern 209 is then ashed. For example, among the photoresist pattern 209, the photoresist pattern 209 corresponding to the region having a relatively low thickness is removed and the photoresist pattern 209 corresponding to the region having a relatively high thickness is left behind.

Referring to FIG. 5J, the metal layer 208 exposed by the ashed photoresist pattern 209a is etched using the ashed photoresist pattern 209a as a mask. Accordingly, the common electrode CE and the common line CL can be disposed on the planarization layer 206. The common electrode CE can be integrally formed on the front surface of the substrate 200 excluding the first and fourth contact holes C1, C4 of the drain area DA. For example, the common electrode CE can be integrally formed on the front surface of the substrate 200 excluding the area “A” shown in FIG. 3. The common electrode CE can be electrically connected to the common line CL. As such, the fifth mask is used.

Referring to FIG. 5K, a second protective film 210 is formed on the front surface of the substrate where the common electrode CE and the common line CL are disposed. For example, the second protective film 210 can be used by stacking an inorganic layer such as a silicon oxide (SiO₂) film or a silicon nitride (SiNx) film in a monolayer or multilayer structure. A fifth contact hole C5 is formed by selectively removing the second protective film 210 corresponding to the location where the fourth contact hole C4 is formed, through exposure and etching processes using a mask. As such, the sixth mask is used.

Referring to FIG. 5L, a transparent conductive film such as ITO (indium tin oxide) or IZO (indium zinc oxide) is deposited on the second protective film 210. Then, a pixel electrode PXL is formed by selectively removing the transparent conductive film through exposure and etching processes using a seventh mask. The pixel electrode PXL can be electrically connected to the drain area DA of the thin film transistor Tr through the first, fourth and fifth contact holes C1, C4 and C5. In order to form a fringe field depending on the voltage applied to the common electrode CE and the voltage applied to the pixel electrode PXL, the pixel electrode PXL can have a plurality of slits. As such, the seventh mask is used.

A color filter array substrate including a black matrix layer formed in a portion excluding each pixel area on a counter substrate, a color filter layer formed in each pixel area, and an overcoat layer covering the black matrix layer and the color filter layer and the thin film transistor array substrate described above are bonded with a predetermined gap therebetween, and the gap between the thin film transistor array substrate and the color filter array substrate is filled with a liquid crystal layer, thereby manufacturing a liquid crystal display panel.

In the display apparatus and the method of manufacturing the same according to embodiments of the present disclosure as described above, gate lines and data lines are formed as single wiring, and the conductive layer is provided to the active layer and is thus connected to the data lines, so that the number of mask processes can be reduced.

Further, since the number of mask processes can be reduced, the production cost for the display apparatus according to aspects of the present disclosure can be reduced.

Further, according to aspects of the present disclosure, since the number of mask processes can be reduced, energy consumed to produce the display apparatus can be reduced, and generation of greenhouse gas due to the manufacturing process can be reduced, thereby achieving ESG (environmental/social/governance) goals.

Further, according to aspects of the present disclosure a backlight light shielding layer can be formed by applying a gate electrode material and a flip panel to the semiconductor area of the active layer.

As is apparent from the foregoing, a display apparatus and a method of manufacturing the same according to embodiments of the present disclosure have the following effects.

Since gate lines and data lines are formed as single wiring and a conductive layer is provided to an active layer and is thus connected to the data lines, the number of mask processes can be reduced.

Since the number of mask processes can be reduced, the production cost can be reduced.

Since the number of mask processes can be reduced, energy consumed to produce the display apparatus can be reduced, and generation of greenhouse gases due to the manufacturing process can be reduced, thereby achieving ESG (environmental/social/governance) goals.

A backlight light shielding layer can be formed by applying a gate electrode material and a flip panel to the semiconductor area of the active layer.

The effects according to embodiments are not limited to the foregoing, and more diverse effects are included in the present disclosure.

The present disclosure is not limited to the aforementioned embodiments and the attached drawings, and it will be apparent to those skilled in the art to which the present disclosure pertains that various substitutions, modifications, and changes are possible within a scope that does not depart from the technical spirit of the present disclosure.

What is claimed is:

1. A display apparatus, comprising:
gate lines extending in a first direction;
data lines extending in a second direction intersecting the gate lines and extending discontinuously in an area overlapping the gate lines;
a thin film transistor having an active layer and disposed in a pixel area defined by the gate lines and the data lines intersecting each other; and
a pixel electrode connected to the thin film transistor,
wherein the data lines extending discontinuously in the area overlapping the gate lines are electrically connected to each other by the active layer of the thin film transistor.

2. The display apparatus according to claim 1, wherein the gate lines and the data lines are disposed on an identical layer and include an identical material.

3. The display apparatus according to claim 1, wherein the active layer of the thin film transistor comprises:
a semiconductor layer, and
a conductive layer disposed on the semiconductor layer,
wherein a portion of the conductive layer corresponding to a channel area of the thin film transistor is removed, and areas where the conductive layer remains are a source area and a drain area of the thin film transistor.

4. The display apparatus according to claim 3, wherein the data lines extending discontinuously in the area overlapping the gate lines are electrically connected to each other by the conductive layer of the active layer.

5. The display apparatus according to claim 3, further comprising:
a planarization layer disposed on the thin film transistor;
a common electrode disposed on the planarization layer; and
a protective film disposed on the common electrode to protect the common electrode,
wherein the planarization layer and the protective film have a contact hole so that the drain area of the thin film transistor is exposed.

6. The display apparatus according to claim 5, wherein the pixel electrode is disposed on the protective film and electrically connected to the drain area of the thin film transistor through the contact hole of the planarization layer and the protective film.

7. The display apparatus according to claim 1, wherein the pixel electrode has a plurality of slits.

8. The display apparatus according to claim 1, wherein the display apparatus is a liquid crystal flat panel display apparatus.

9. A method of manufacturing a display apparatus, the method comprising:
forming an active layer on a substrate, the active layer including a source area, a channel area and a drain area, the active layer comprising a semiconductor layer and a conductive layer disposed thereon, wherein the conductive layer corresponding to the channel area is removed;
forming a gate insulating film on the substrate on which the active layer is disposed;
forming a first contact hole to expose the drain area of the active layer and second and third contact holes to expose the source area of the active layer by selectively removing the gate insulating film;
forming gate lines extending in a first direction on the gate insulating film, a gate electrode protruding from the gate lines, and data lines extending in a second direction intersecting the gate lines to extend discontinuously in an area overlapping the gate lines;
forming a first protective film on a surface of the substrate to cover the gate lines, the data lines, and the gate electrode;
forming a planarization layer on the first protective film;
forming a fourth contact hole by selectively removing the first protective film and the planarization layer at a location where the first contact hole is formed;
forming a common electrode and a common line on the planarization layer;
forming a second protective film on the surface of the substrate where the common electrode and the common line are disposed;
forming a fifth contact hole by selectively removing the second protective film corresponding to a location where the fourth contact hole is formed; and
forming a pixel electrode on the second protective film so as to be electrically connected to the drain area through the first, fourth and fifth contact holes.

10. The method according to claim 9, wherein the gate lines and the data lines are formed on an identical layer using an identical material.

11. The method according to claim 9, wherein the forming the active layer comprises:
sequentially forming the semiconductor layer and the conductive layer on the substrate,
forming a photoresist pattern defining the active layer through exposure and development processes using a halftone mask on the conductive layer,
removing the semiconductor layer and the conductive layer using the photoresist pattern as a mask, and
ashing the photoresist pattern and removing a portion of the conductive layer corresponding to the channel area using the ashed photoresist pattern as a mask.

12. The method according to claim 9, wherein the data lines extending discontinuously in the area overlapping the gate lines are electrically connected to each other by the conductive layer through the second and third contact holes.

13. The method according to claim 9, wherein the gate electrode is formed on the gate insulating film in the channel area of the active layer.

14. The method according to claim 9, wherein the forming the common electrode and the common line comprises:
sequentially forming a transparent conductive film and a metal layer on the planarization layer,
forming a photoresist pattern defining the common electrode through exposure and development processes using a halftone mask on the metal layer,
patterning the common electrode by removing the transparent conductive film and the metal layer using the photoresist pattern as a mask,
ashing the photoresist pattern, and
forming the common line by removing the metal layer using the ashed photoresist pattern as a mask.

15. The method according to claim 9, wherein the pixel electrode has a plurality of slits.

16. The method according to claim 9, wherein the display apparatus is a liquid crystal flat panel display apparatus.
